(19) United States
(12) Patent Application Publication
(10) Pub. No.: US 2015/0131382 A1
(43) Pub. Date: May 14, 2015

(54) SEMICONDUCTOR STORAGE DEVICE AND METHOD OF MANUFACTURING THE SAME

(71) Applicant: KABUSHIKI KAISHA TOSHIBA, Minato-ku (JP)

(72) Inventor: Yoshiaki HIMENO, Yokkaichi (JP)

(73) Assignee: KABUSHIKI KAISHA TOSHIBA, Minato-ku (JP)

(21) Appl. No.: 14/188,927

(22) Filed: Feb. 25, 2014

Related U.S. Application Data
(60) Provisional application No. 61/903,498, filed on Nov. 13, 2013.

(51) Int. Cl. H01L 21/308; H01L 21/033; G11C 16/04; H01L 21/311

(52) U.S. Cl. CPC H01L 21/3086; H01L 21/31144; H01L 21/0338; G11C 16/04
USPC 365/185.18; 438/703

(57) ABSTRACT

A semiconductor storage device including a memory cell array including a memory cell and a circuit element including first wirings and a selection element, the first wirings having a wiring width smaller than a resolution limit of an exposure apparatus. The first wirings extend in a first direction and are aligned in a second direction crossing with the first direction. A second wiring, being one of the first wirings, is cut by at least one cut region. The first wiring adjacent to the second wiring in the second direction extends continuously in the first direction in a portion adjacent to the cut region in the second direction.

### CROSS-REFERENCE TO RELATED APPLICATION(S)

This application is based upon and claims the benefit of priority from U.S. Provisional Patent Application No. 61/903,498, filed on, Nov. 13, 2013 the entire contents of which are incorporated herein by reference.

### FIELD

Embodiments disclosed herein generally relate to a semiconductor storage device and a method of manufacturing the same.

### BACKGROUND

In the manufacturing process flow of semiconductor devices, a sidewall transfer technique is used in which a sidewall formed around a mandrel is used as a pattern for forming small patterns beyond an exposure limit of optical lithography (a resolution limit of an exposure apparatus).

Pattern cutting, in which a portion of a wiring pattern is cut, may be carried out during the formation of wiring patterns using sidewall transfer processing. However, because the pattern (cut pattern) cut by the pattern cutting is an isolated pattern, it is difficult to apply the sidewall transfer technique. Thus, it is difficult to reduce the size of the cut pattern to be smaller than the resolution limit of the exposure apparatus. As a result, the area of cut patterns may increase and thereby increase the number of wiring patterns divided by the cut patterns.

### BRIEF DESCRIPTION OF THE DRAWINGS

FIG. 1 is one example partially illustrating an electrical configuration of a memory cell region and a peripheral circuit region of a NAND Flash memory device of one embodiment.

FIG. 2 is one example illustrating a diagram illustrating an electrical configuration of a bit line hook-up circuit.

FIG. 3 is one example illustrating a plan view illustrating a cut portion of a wiring of a bit line hook-up circuit.

FIGS. 4A and 4B to FIGS. 11A and 11B and FIG. 12 are each one example of a figure illustrating the manufacturing process flow of the present embodiment.

### DESCRIPTION

In one embodiment, a semiconductor storage device includes a memory cell array including a memory cell and a circuit element including first wirings and a selection element, the first wirings having a wiring width smaller than a resolution limit of an exposure apparatus. The first wirings extend in a first direction and are aligned in a second direction crossing with the first direction. A second wiring, being one of the plurality of the first wirings, is cut by at least one cut region. The first wiring adjacent to the second wiring in the second direction extends continuously in the first direction in a portion adjacent to the cut region in the second direction.

### Embodiments

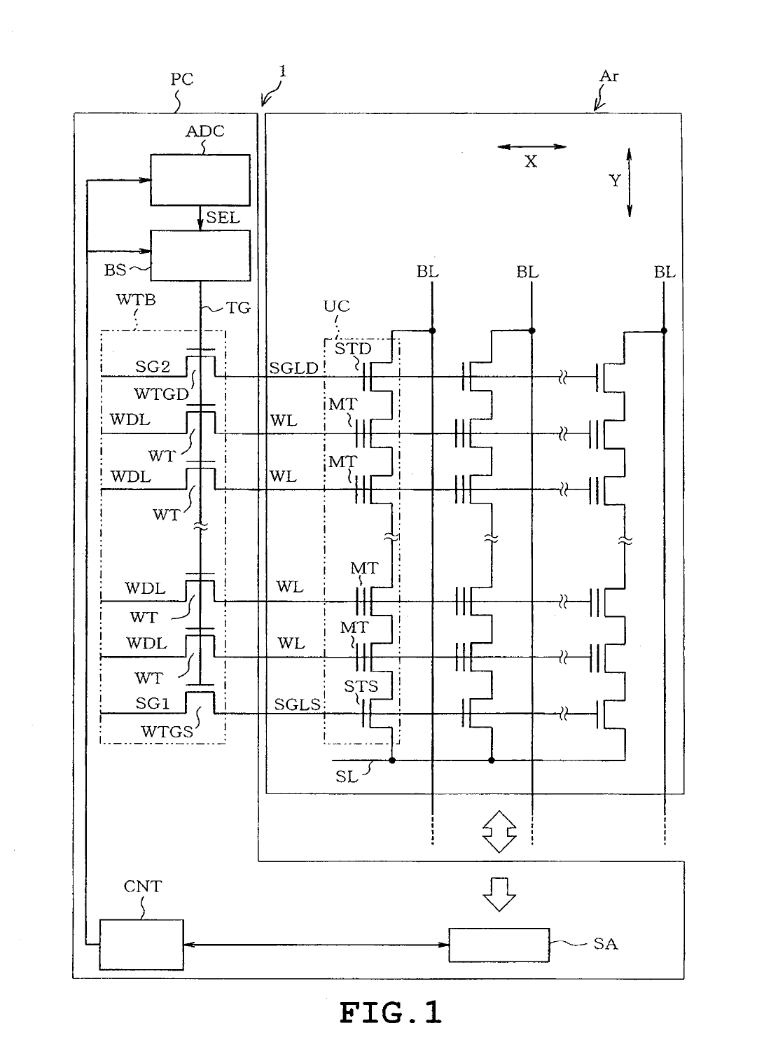

Embodiments directed to a semiconductor storage device are described hereinafter through a NAND flash memory device application with references to FIGS. 1 to 12. In the following description, elements identical in functionality and structure are identified by identical reference symbols. The drawings are schematic and are not drawn to scale and thus, do not reflect the actual measurements of the features such as the correlation of thickness to planar dimensions and the relative thickness of different layers. Further, directional terms such as up, down, left, and right are used in a relative context with an assumption that the worked surface, on which circuitry is formed of the later described semiconductor substrate faces up. Thus, the directional terms do not necessarily correspond to the directions based on gravitational acceleration.

In the following description, XYZ orthogonal coordinate system is used for ease of explanation. In the coordinate system, the X direction and the Y direction indicate directions parallel to the surface of a semiconductor substrate and are orthogonal to one another. The X direction indicates the direction in which word line WL extends, and the Y direction, being orthogonal to the X direction, indicates the direction in which bit line BL extends. The Z direction indicates the direction orthogonal to both the X direction and the Y direction. The embodiments will be described based on a NAND flash memory application which is one example of a semiconductor storage device. Alternative technologies will be mentioned as required.

FIG. 1 is one schematic example of a diagram illustrating an electrical configuration of NAND flash memory device in part according to one embodiment. As shown in FIG. 1, NAND flash memory device 1 is provided with memory cell array Ar, peripheral circuit region PC and input/output interface circuitry not shown. Memory cell array Ar is configured by multiplicity of memory cells arranged in a matrix. Peripheral circuit PC is configured to read/program/erase each of the memory cells in memory cell array Ar.

Memory cell array Ar located in the memory cell region includes multiplicity of units of cells referred to as cell units UC. Cell unit UC has 2^{k}=m number (for example 32 (=m)) of series connected memory-cell transistors MT situated between a couple of select transistors STD and STS. Select transistors STD are connected to bit line BL, whereas select transistors STS are connected to source line SL.

A block includes n number of cell units UC aligned in the X direction (row direction: the left and right direction as viewed in FIG. 1). Memory cell array Ar includes multiple blocks aligned in the Y direction (column direction: the up and down direction in FIG. 1). FIG. 1 only shows one block for simplicity.

The memory cell region is surrounded by the peripheral circuit region and peripheral circuit PC is located in the periphery of memory cell array Ar. Peripheral circuit PC includes controller CNT, address decoder ADC, sense amplifier SA, step-up circuit BS provided with a charge pump circuit, and transfer transistor WTB. Address decoder ADC is electrically connected to transfer transistor WTB through step-up circuit BS.

Controller CNT controls address decoder ADC, sense amplifier SA, step-up circuit BS having a charge pump circuit, a transfer transistor WTB, or the like based on commands given from external components. Address decoder ADC selects a given block based on an incoming address signal provided from an external component and sends block selection signal SEL to step-up circuit BS. Step-up circuit BS, when given a block selection signal, steps up the drive voltage received from an external component and supplies the stepped up voltage, being stepped up to a predetermined level, to transfer transistors WTGD, WTGS, and WT by way of transfer gate line TG.

Transfer transistor WTB is provided with transfer gate transistor WTGD, transfer gate transistor WTGS, word line transfer gate transistor WT, or the like. Transfer transistor WTB is given on a block by block basis.

Transfer gate transistor WTGD is configured such that either of the drain and source is connected to select gate driver line SG2, and the remaining other is connected to select gate line SGLD. Transfer gate transistor WTGS is configured such that either of the drain and source is connected to select gate driver line SG1, and the remaining other is connected to select gate line SGLS. Each of word line transfer gate transistor WT is configured such that either of the drain and source is uniquely connected to word line drive signal line WDL respectively, and the remaining other is uniquely connected to word line WL.

Gate electrodes SG of select transistors STD of the aligned cell units UC aligned in the X direction are electrically connected by common select gate line SGLD. Similarly, gate electrodes SG of select transistors STS of the cell units UC aligned in the X direction are electrically connected by common select gate line SGLS. As described earlier, the source of each select transistor STS is connected to common source line SL. Gate electrodes MG of memory-cell transistors MT of the cell units UC aligned in the X direction are electrically connected by common word line WL respectively.

Gate electrodes of transfer transistors WTGD, WTGS, and WT are interconnected by common transfer gate line TG, which is turn, connected to an output terminal of step up circuit BS for supplying stepped up voltage.

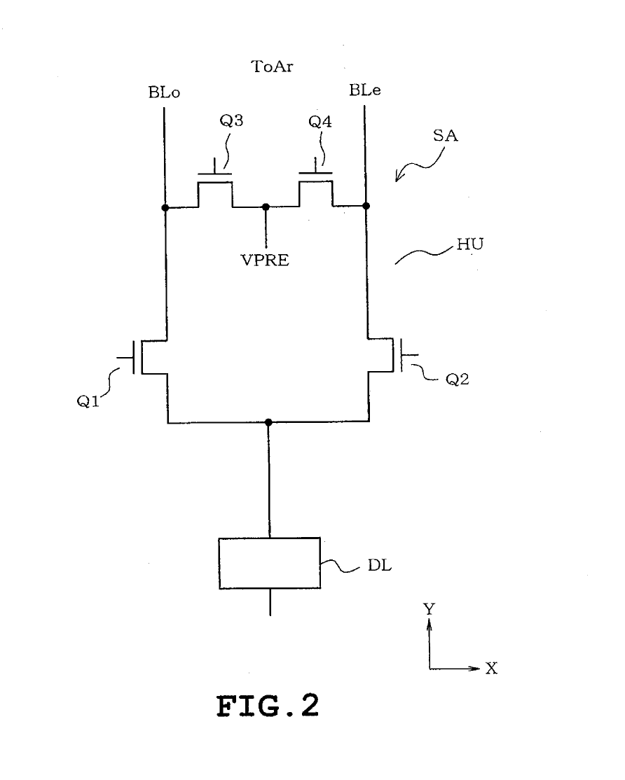

As shown in FIG. 2, sense amplifier SA is connected to bit line hook-up circuit HU and data latch circuit DL which are connected to every two adjacent bit lines among the bit lines extending from the memory cell region. Bit line hook-up circuit HU is provided with selection element Q1 (one example of which is transistor Q1) and selection element Q2 (one example of which is transistor Q2). Selection element Q1 connects odd number bit line BLo to data latch circuit DL. Selection element Q2 connects even number bit line BLe to data latch circuit DL. Further, bit line hook-up circuit HU is provided with selection element Q3 (one example of which is transistor Q3) and selection element Q4 (one example of which is transistor Q4). Selection element Q3 connects odd number bit line BLo to control line VPRE. Selection element Q4 connects even number bit line BLe to control line VPRE. Data latch circuit DL is capable of detecting and storing the voltage of bit line BL. Data latch circuit DL is connected to an TO line and is capable of transferring the stored data (voltage) to another circuit through the IO line. Further, data latch circuit DL is capable of receiving the data (voltage) to be programmed to the memory cell transistor from another circuit through the IO line.

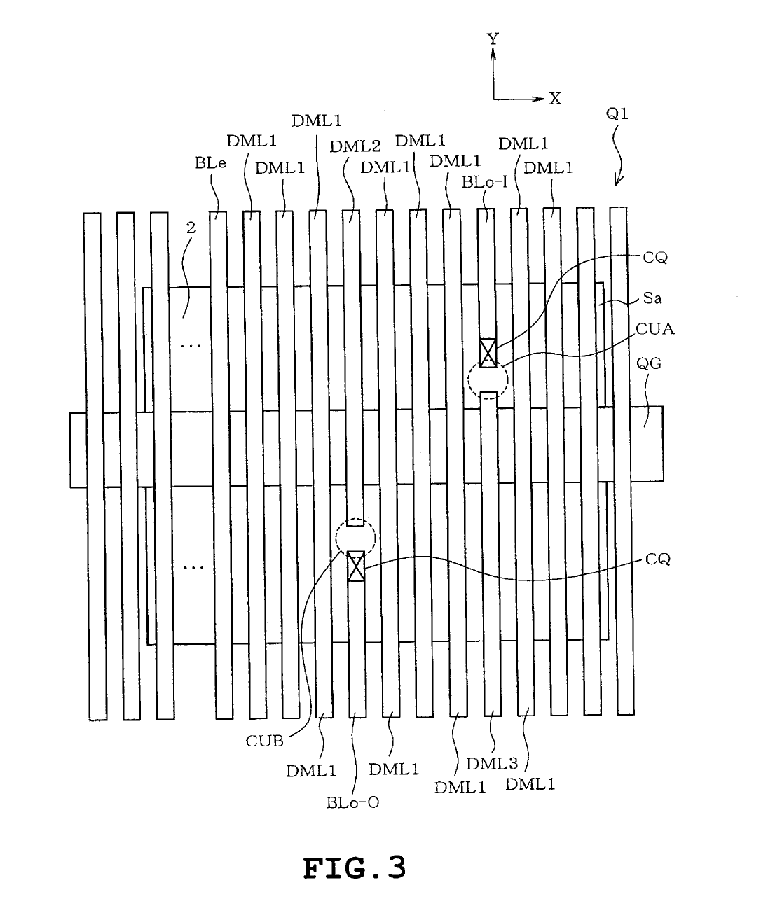

FIG. 3 illustrates one example of a layout of transistor Q1 portion or transistor BLS of bit line hook-up circuit HU. Transistor Q1 includes a rectangular element region Sa formed in silicon substrate 2 serving as a semiconductor substrate, and gate electrode QG extending across the central portion of element region Sa. An interlayer insulating film is formed above element region Sa and gate electrode QG. Wirings (32 for example) are disposed in the interlayer insulating film so as to cross over the upper portion of gate electrode QG. The wirings include bit lines BLo and BLe. Bit lines BLo and BLe may be formed using, for example, a damascene process in which a copper wiring pattern is filled in a recess formed into the interlayer insulating film.

Bit lines BLo and BLe are disposed alternately in memory cell array Ar. In the region where bit lines BLo and BLe extending from memory cell array Ar are hooked up to peripheral circuit region PC, dummy lines DML1 are disposed between bit line BLo and bit line BLe. FIG. 3 shows three dummy lines DML1 disposed in an electrically floating state between each bit line BLo and BLe. However, the number of dummy lines DML1 may be less than three. Insulation breakdown voltage between bit line BLo and bit line BLe is improved by disposing dummy lines DML between the bit lines. Bit lines BLo-O, being hooked up to bit line BLo and data latch circuit Dl, are respectively connected to source/drain region of transistor Q1 by way of contact CQ. Bit line BLo-O is connected to the data latch circuit DL.

Further, bit lines BLo-I and BLo-O and dummy line DML1 extend in the Y direction as viewed in FIG. 3, and are disposed in the X direction with a regular pitch which is smaller than the critical dimension of lithography. The widths of bit lines BLo-I and BLo-O and dummy line DML1 are smaller than the critical dimension of lithography.

Bit lines BLo-I and BLo-O, connected to transistor Q1, have cut regions CUA and CUB. Bit lines BLo-I and BLo-O are cut at cut regions CUA and CUB, respectively. The cut regions may be collectively referred to as cut region CU. Cut regions CUA and CUB are regions where bit lines BLo-I and BLo-O are respectively divided. A portion of bit line BLo-O located in memory cell array Ar side of cut region CUB serves as dummy line DML2. Dummy line DML2 may be used as a hook-up wiring extending toward memory cell array Ar side of transistor Q1. A portion of bit line BLo-I located in data latch circuit DL side of cut region CUA serves as dummy line DML3. Dummy line DML3 may be used as a hook-up wiring which is extending toward data latch circuit DL side of transistor Q1. Further, dummy lines DML1 disposed between cut regions CUA and CUB may be connected to the gate electrode of transistor Q1. Thus, dummy line DML1 may be used as signal lines that turn transistor Q1 ON and OFF. Further, dummy lines DML1 may be used as shield lines by being given ground voltages. Further, it is possible to place dummy lines DML1 in floating states. Further, dummy lines DML1 disposed between bit line BLo-O and bit line BLe may be used as shield wirings.

Transistor Q2 is disposed in data latch circuit DL side (the lower side of the Y direction in the figures) of transistor. Q1. Bit line BLe has cut region CU in transistor Q2 which is similar to cut region CU for bit line BLo. The structure described above is present embodiment described through a NAND flash memory application.

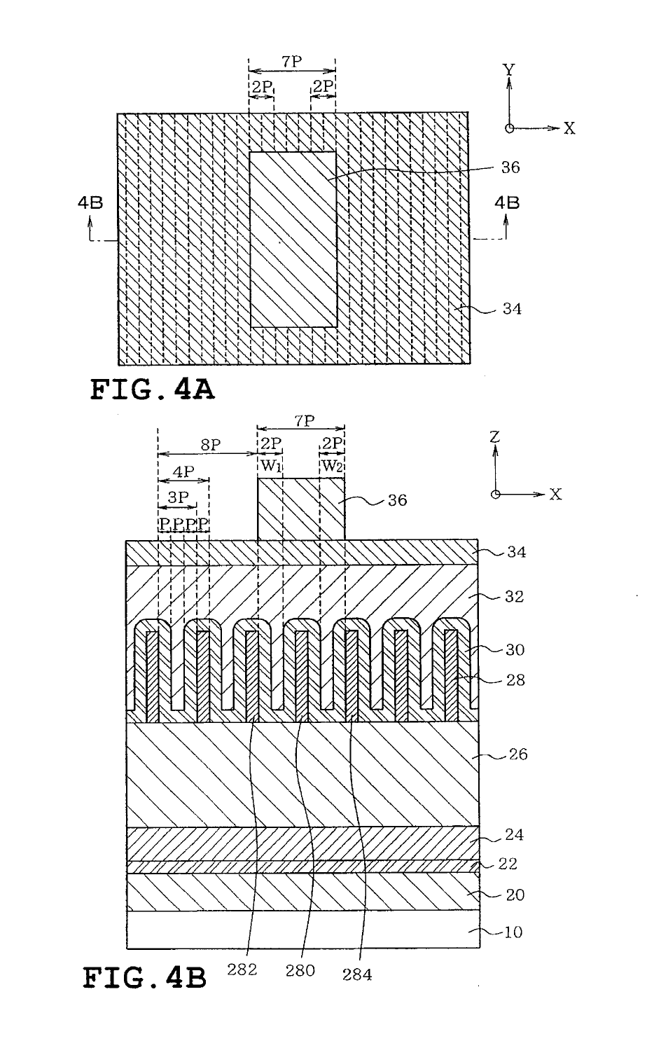

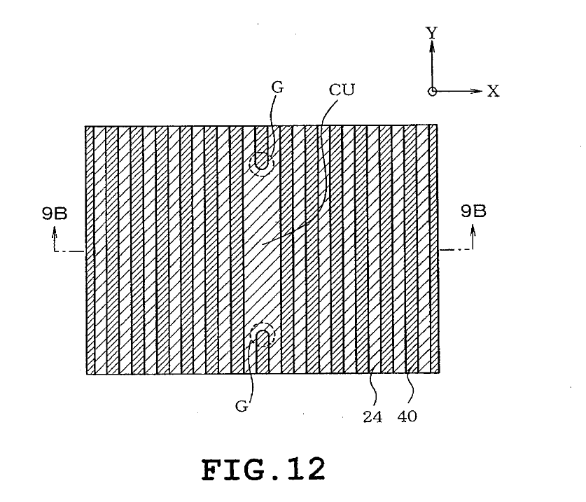

Next, a description will be given on a manufacturing process flow of a NAND flash memory device of present embodiment with reference to FIGS. 4A and 4B to FIGS. 11A to 11B and to FIG. 12. FIGS. 4A and 4B to FIGS. 11A to 11B and to FIG. 12 are examples of figures illustrating the manufacturing process flow of present embodiment and each illustrate one phase of the manufacturing process flow of a region including cut region CU.

FIG. 4A illustrates one example of a plan view of a region including cut region CU. FIG. 4B illustrates one example of a vertical cross sectional view of taken along line 4B-4B of FIG. 4A. Line 4B-4B transverses cut region CU. In FIG. 4A, the planar shape (though not perceivable in plan view) transferred by second mask film 30 is indicated in broken lines.

First, as shown in FIGS. 4A and 4B, first interlayer insulating film 20, stopper insulating film 22, second interlayer insulating film 24, and first mask film 26 are formed above semiconductor substrate 10. A silicon substrate having a p conductivity type, for example, may be used as semiconductor substrate 10. First interlayer insulating film 20 and second interlayer insulating film 24 may be formed of a silicon oxide film formed by CVD (Chemical Vapor Deposition) using TEOS (Tetraethyl orthosilicate, tetraethoxysilane) as a source gas. The formed silicon oxide film may be densified by thermal treatment. The densified silicon oxide film is etched at low etch rate by etchants such as diluted hydrofluoric acid solution.

Stopper insulating film 22 may be formed of a silicon nitride film formed, for example, by plasma CVD. First mask film 26 may be formed of, for example, an amorphous silicon film formed by CVD at the temperature of 500 degrees Celsius. Mandrel 28 may be formed in a line-and-space shape above the silicon film. Second mask film 30 may be formed conformally above the surface of mandrel 28. Mandrel 28 may be formed of, for example, a coating type carbon film.

Mandrel 28 may be patterned by sidewall transfer method. Multiple mandrels 28 extend in the Y direction as viewed in the figures and are aligned in the X direction in a line and space arrangement. Mandrel 28 has a columnar cross section. Second mask film 30 may be formed of, for example, a silicon oxide film formed by plasma CVD. Second mask film 30 is formed under conditions providing good coverage and conformally covers mandrel 28

Next, the repeating pitch and width formed by mandrel 28 and second mask film 30 will be explained. Mandrels 28 extend in the Y direction as viewed in the figures and have pitch P in the X direction as described earlier to exhibit a line-and-space shape. Mandrels 28 may be formed by sidewall transfer method. For example, when the size of the repeating pitch of mandrel 28 is represented as 4P, the critical size of repeating pitch which can be formed by lithography is 8P which is a double of the size of the repeating pitch of mandrel 28. Approximately 4P, which is approximately half the critical size of the repeating pitch which can be formed by lithography, is the size of exposure limit (minimum critical size). When sidewall transfer method is used for formation of mandrel 28, it is possible to use subresolution methods such as off-axis illumination and phase shift methods in the lithography for forming a mandrel for mandrel 28.

The second mask film 30 is formed so as to have thickness P. As a result, the distance between mandrels 28 adjacent to one another in the X direction is represented as 3P and the width taken in the X direction of later described trenches between second mask films 30 is represented as P. This means that the line width and space width of second mask film 30 are less than the exposure limit (minimum critical size) of lithography, in other words, less than the resolution limit of an exposure apparatus.

Then, carbon-containing film 32 is formed. For example, an organic film such as a coating type carbon film may be used as carbon-containing film 32. Carbon-containing film 32 fills the trenches formed by second mask film 30 and is formed so as to have a planar surface. Then, cap insulating film 34 is formed. A silicon oxide film formed, for example, by SOG (Spin On Glass) may be used as cap insulating film 34.

Next, resist 36 is formed above cap insulating film 34. Resist 36 may be formed by lithographic patterning. Resist 36 is formed in a rectangular shape so as to cover cut region CU. It is possible to form resist 36 at the exposure limit (minimum critical size) of lithography. Because resist 36 is an isolated pattern, it is difficult to reduce its feature size as compared to a repeating pattern. Thus, in present embodiment, the lateral width of resist 36 is formed at 7P.

At this instance, mandrel 28 located immediately below resist 36 is represented as mandrel 280, mandrel 28 leftwardly adjacent to mandrel 280 in the X direction is represented as mandrel 282, and similarly, the rightwardly adjacent mandrel 28 is represented as mandrel 284. Region W1 is a region having a width of approximately 2P in the X direction right side from the right end of mandrel 282. Region W2 is a region having a width of approximately 2P in the X direction left side from the left end of mandrel 284.

The X direction right end and left end of resist 36 may exist anywhere as long as they are in the shown ranges of region W1 and region W2. It is also possible to form resist 36 by lithography and thereafter reduce its size by slimming. In such case also, the right end and left end of resist 36 may exist anywhere as long as they are in the shown ranges of region W1 and region W2.

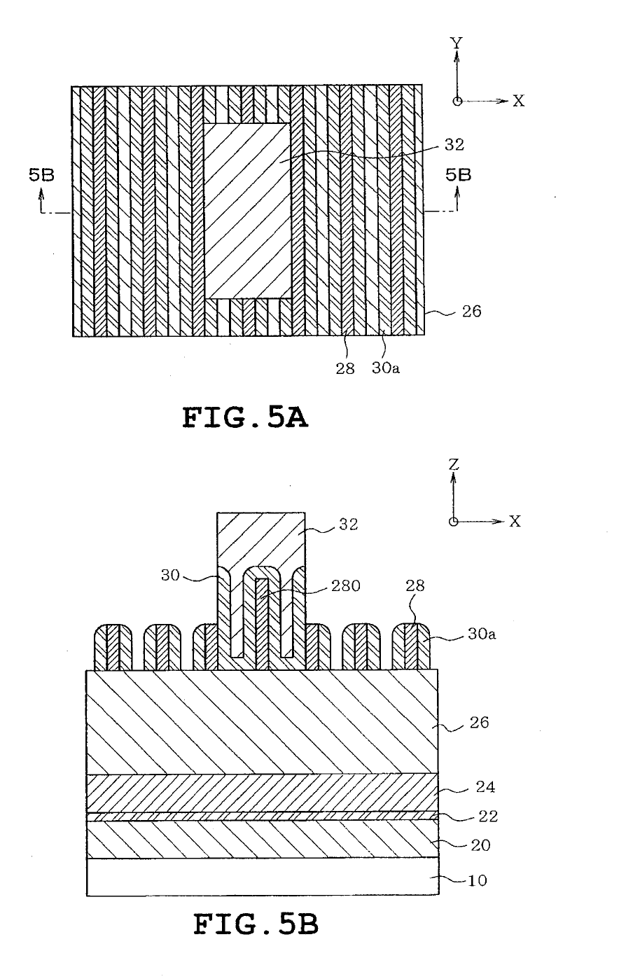

FIG. 5A illustrates one example of a plan view of a region including cut region CU. FIG. 5B illustrates one example of a vertical cross sectional view taken along line 5B-5B of FIG. 5A.

As shown in FIGS. 5A and 5B, cap insulating film 34 and carbon-containing film 32 are selectively etched under anisotropic conditions by RIE using resist 36 as a mask. Then, second mask film 30 is etched back by RIE under anisotropic conditions. The etch back is carried out under conditions in which the etch rates of mandrel 28 and second mask film 30 are substantially the same. When resist 36 is dissipated during the etching of carbon-containing film 32, the etching (etch back) progresses with cap insulating film 34 serving as the etch mask. As a result, the pattern of resist 36 is transferred to carbon-containing film 32.

Below carbon-containing film 32, second mask film 30 remains so as to cover mandrel 28 (mandrel 280) located in the central portion of FIG. 5B. The upper surfaces of portions of mandrels 28 uncovered by carbon-containing film 32 are exposed. Second mask film 30 is etched back and second mask films 30a shaped like sidewalls are formed along the side surfaces of mandrels 28.

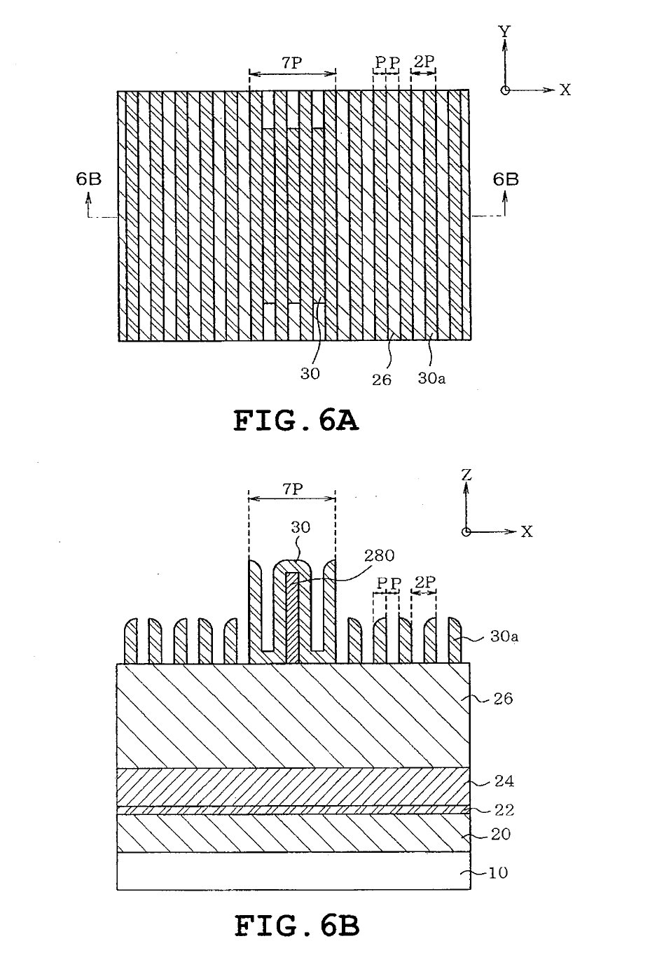

FIG. 6A illustrates one example of a plan view including cut region CU. FIG. 6B illustrates one example of a vertical cross sectional view taken along line 6B-6B of FIG. 6A.

As shown in FIGS. 6A and 6B, carbon-containing film 32 and mandrel 28 are selectively removed. As a result, second mask film 30 is formed in which the pattern of resist 36 is transferred and mandrel 280 remains below the central portion of second mask film 30 when viewed from the Z direction. In regions which are not located below resist 36, second mask film 30 is transformed into second mask film 30a shaped like pillars in a line-and-space arrangement. Both the line width and the space width of the pillar-shaped second mask film 30a are P and thus, the width of repeating pitch is 2P as viewed in the X direction.

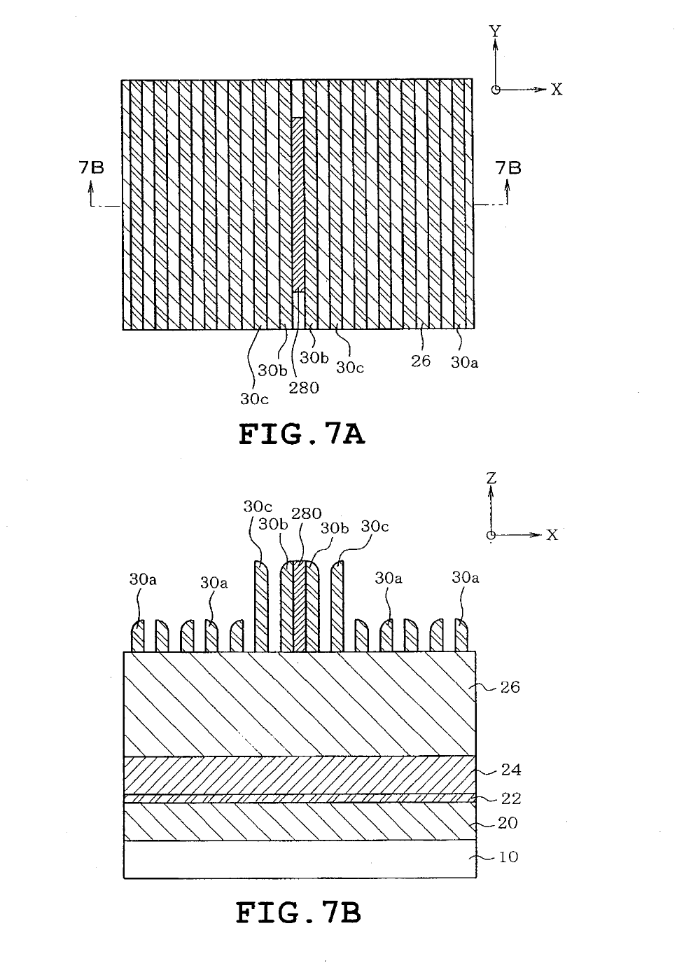

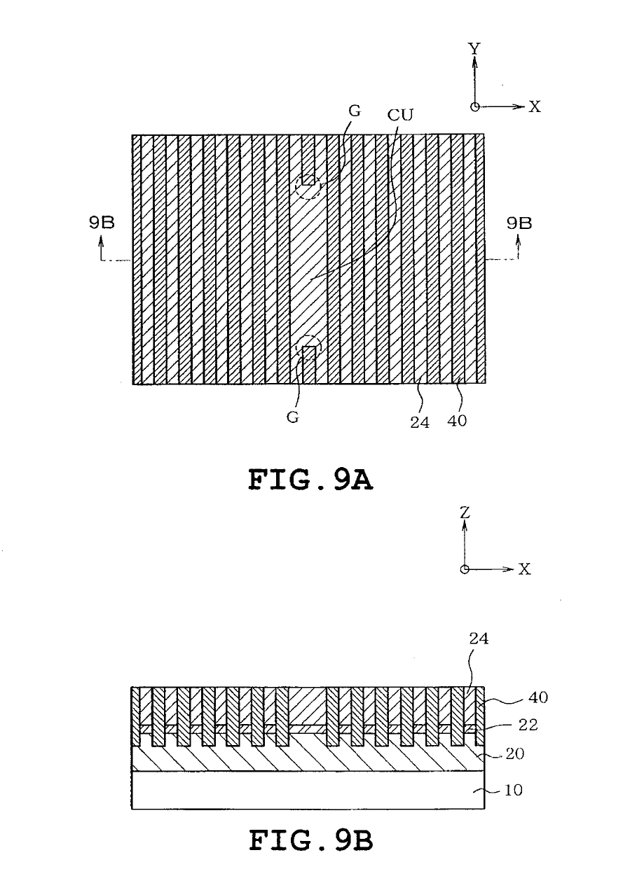

Carbon-containing film 32 and mandrel 28 may be removed by RIE using oxide plasma. The RIE may be carried out in conditions providing strong vertical components (anisotropic conditions). By applying such condition, the terminating ends of mandrel 280 in the Y direction as viewed in FIG. 7A are shaped like a straight line, and as shown in later described FIG. 9A, the planar shapes of the terminating ends of pattern edge G of copper wiring 40 in cut region CUA are shaped like a straight line.

Carbon-containing film 32 and mandrel 28 may be removed by etching carried out under conditions providing strong isotropy (isotropic conditions). In such case, the planar shape of the terminating ends of pattern edge G of copper wiring 40 become rounded as shown in later described FIG. 12.

FIG. 7A illustrates one example of a plan view of a region including cut region CU. FIG. 7B illustrates one example of a vertical cross sectional view taken along line 7B-7B of FIG. 7A. Line 7B-7B transverses cut region CU.

As shown in FIGS. 7A and 7B, second mask film 30 is etched back by RIE under anisotropic conditions in order to remove second mask film 30 remaining above the upper surface of mandrel 280 and above the upper surface of first mask film 26. In other words, the etching removes second mask film 30 in the amount equivalent to the thickness of second mask film 30 formed above the upper surface of mandrel 280. The etching may be carried out with substantially the same etch rate for mandrel 28 (mandrel 280) and second mask film 30. The etching exposes the upper surface of mandrel 280 and forms second mask film 30b shaped like a sidewall based second mask film 30 on the side surfaces of mandrel 280.

Further, second mask films 30c shaped like isolated pillars are formed by dividing second mask film 30 remaining in one piece above first mask film 26. It is possible to form second mask films 30a, 30b, and 30c in the above described manner.

As described above, it is possible to form second mask films 30a, 30b, and 30c by sidewall transfer processing method. When mandrel 28 is formed in the first sidewall transfer processing method, second mask films 30a, 30b, and 30c are formed in the second sidewall transfer processing method (double sidewall transfer processing method). The line width and the space width of the pillar shaped second mask films 30a, 30b, and 30c are formed in a smaller (thinner) size than the exposure limit (minimum critical size) of lithography, in other words, the resolution limit of the exposure apparatus. Further, mandrel 280 is formed in a portion located between second mask films 30b. Cut region CU is later formed in the portion where mandrel 280 is formed.

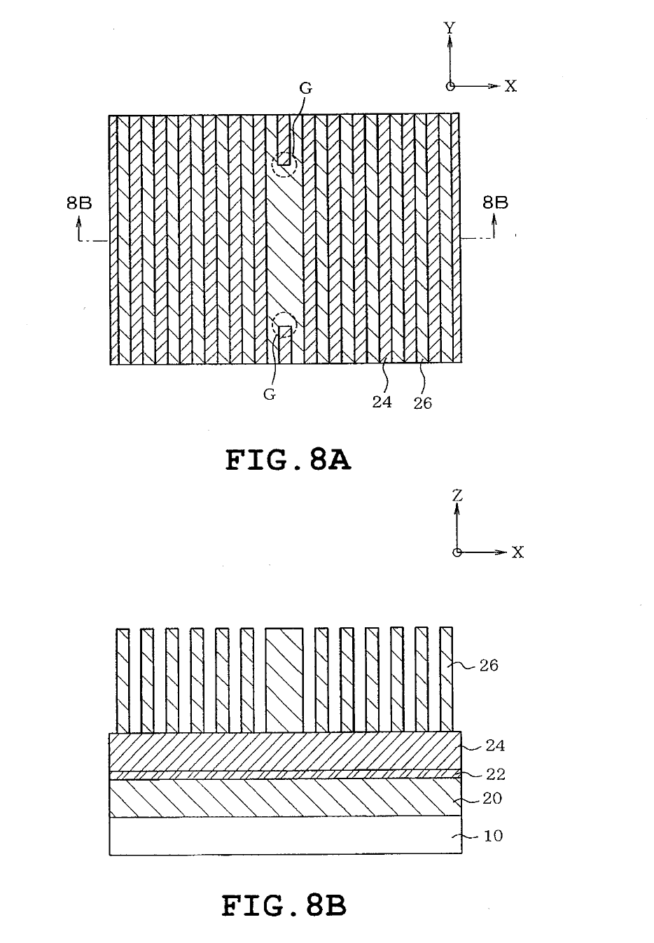

FIG. 8A illustrates one example of a plan view of a region including cut region CU. FIG. 8B illustrates one example of a vertical cross sectional view taken along line 8B-8B of FIG. 8A.

As shown in FIG. 8A and FIG. 8B, second mask films 30a, 30b, and 30c and mandrel 280 are used as masks to etch first mask film 26. The etching may be carried out by RIE under anisotropic conditions using second interlayer insulating film 24 as a stopper. Then, second mask films 30a, 30b, and 30c and mandrel 280 are removed. Mandrel 280 may be removed, for example, by ashing using oxygen plasma.

In present embodiment, second mask films 30a, 30b, and 30c are formed of a silicon oxide film and thus, may be removed, for example, by diluted hydrofluoric acid solution. At this instance, by densifying second interlayer insulating film 24 by thermal treatment, it is possible to reduce the etch rate of second interlayer insulating film 24 by hydrofluoric acid solution compared to the etch rate of second mask film 30 by diluted hydrofluoric acid solution. Thus, it is possible to selectively remove second mask film 30 without etching second interlayer insulating film 24 by diluted hydrofluoric acid solution. The pattern formed by second mask films 30a, 30b, and 30c and mandrel 280 is transferred to first mask film 26 in the above described manner.

FIG. 9A illustrates one example of a plan view of a region including cut region CU. FIG. 9B illustrates one example of a vertical cross sectional view taken along line 9B-9B of FIG. 8A.

As shown in FIGS. 9A and 9B, copper wiring 40 is formed. Copper wiring 40 is formed by damascene method as described below. First, second interlayer insulating film 24 is etched using first mask film 26 as a mask. The etching is carried out by RIE under anisotropic conditions.

The etching of first mask film 26 is carried out using stopper insulating film 22 as an etch stopper. Then, the etching further progresses after modifying the etch condition to etch stopper insulating film 22. At this instance, first interlayer insulating film 20 is used as an etch stopper. First interlayer insulating film 20 may be slightly over etched. Trenches for wiring formation is formed in the above described manner.

Then, first mask film 26 is removed. First mask film 26 may be removed, for example, by a choline solution controlled to high temperatures. The pattern formed by second mask films 30a, 30b, and 30c and mandrel 280 is transferred in the shape of trenches to second interlayer insulating film 24 and stopper film 22 via first mask film 26 in the above described manner. The shapes of trenches formed in second interlayer insulating film 24 is thinner than the exposure limit (minimum critical size) of lithography, in other words, the resolution limit of the exposure apparatus.

Then, copper is filled in the trenches for wiring formation by plating for example, and the excess copper is polished away by CMP (Chemical Mechanical Polishing). Copper wiring 40 is formed by filling the wiring trenches with copper in the above described manner. Thus, it is possible to form copper wiring 40 (bit line) cut in cut region CU as shown in FIG. 9A.

The planar shapes of the terminating ends of pattern edge G of copper wiring 40 in cut region CU are shaped like a straight line because etching is carried out under anisotropic conditions in the process step for removing carbon-containing film 32 and mandrel 28 described with reference to FIGS. 6A and 6B. First interlayer insulating film 20 may have a contact wiring (not shown) that connect to the lower electrode or semiconductor substrate 10 and copper wiring 40 may be formed so as to be connected to the contact wiring.

FIG. 12 illustrates the planar shape when etching is carried out under isotropic conditions in the process step for removing carbon-containing film 32 and mandrel 28 described with reference to FIGS. 6A and 6B

FIG. 12 is a plan view illustrating the process step identical to the process step illustrated in FIG. 9A. In this case, the planar shape of the terminating ends of pattern edge G of copper wiring 40 become rounded as shown in FIG. 12.

In the method of manufacturing a semiconductor device described above, the width of copper wiring 40 is thinner than the exposure limit (minimum critical size) of lithography, in other words, the resolution limit of the exposure apparatus. Further, it is possible to form cut region CU in an isolation width equal to the width of a single bit line BL. It is thus, possible to from cut region CU with a pattern smaller than the lithography limit. Copper wiring 40 (bit line BL) adjacent to cut region CU is not cut.

Further, in the manufacturing method of present embodiment, it is possible to cut any given single bit line BL having a width equal to or less than the minimum critical size. As a result, it is possible to improve process margin and improve layout flexibility.

### Modified Example 1

As described above, silicon oxide film was used as second mask film 30 in present embodiment. However, silicon oxide film may be replaced by titanium oxide (TiO₂). A second mask film using the titanium oxide will be referred to as second mask film 302 hereinafter. Process steps similar to those illustrated in FIGS. 4A and 4B to FIGS. 9A and 9B are carried out as manufacturing process steps. However, processing conditions for processing titanium oxide is used for the processing of second mask film 302.

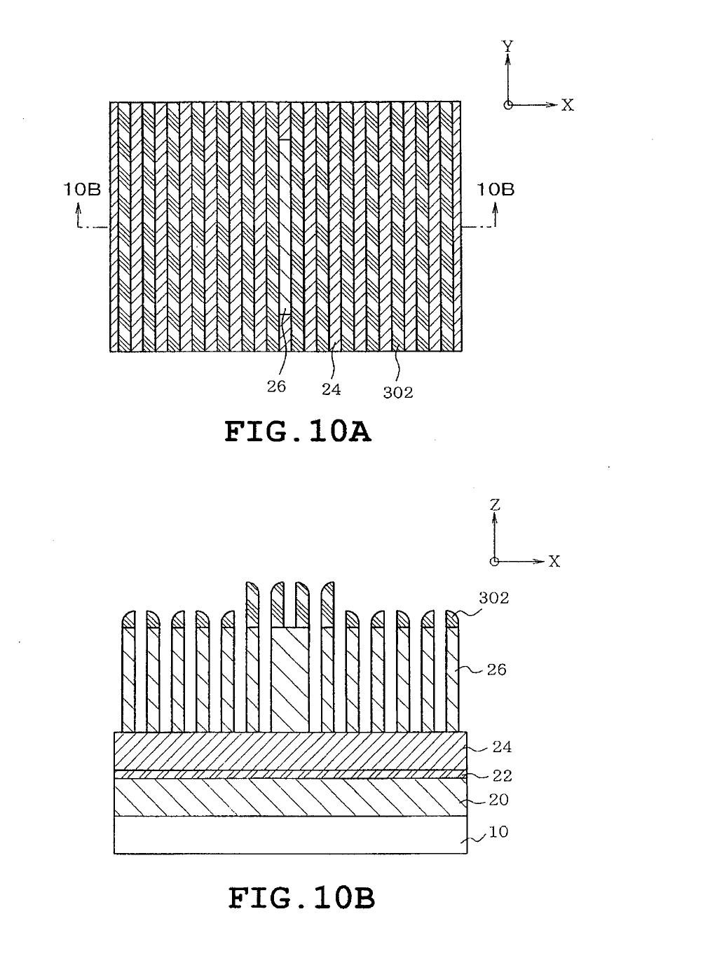

FIGS. 10A and 10B illustrate the process step identical to the process step illustrated in FIGS. 8A and 8B. FIG. 10A illustrates one example of a plan view of a region including cut region CU. FIG. 10B illustrates one example of a vertical cross sectional view taken along line 10B-10B of FIG. 10A.

Because second mask film 302 is formed of titanium oxide, second mask film 302 remains above first mask film 26 in this step. In the step of forming wiring trenches by etching second interlayer insulating film 24, the etching condition is specified so that the etch rates of second mask film 302 and second interlayer insulating film 24 are substantially the same. It is thus, possible to remove second mask film 302 during the etching of second interlayer insulating film 24.

MODIFIED EXAMPLE 1 provides effects similar to those of the present embodiment. Further, tolerability to pattern deformation is increased because physical strength is increased when titanium oxide is used as second mask film 302 as compared to when silicon oxide film is used.

### Modified Example 2

Further, carbon was used as mandrel 28 in the present embodiment as mentioned earlier. However, a silicon nitride film may be used instead of carbon. The silicon nitride film may be formed, for example, by plasma CVD. A mandrel using the silicon nitride film will be referred to as mandrel 282 hereinafter. Process steps similar to those illustrated in FIGS. 4A and 4B to FIGS. 9A and 9B are carried out as manufacturing process steps. However, processing conditions for processing silicon nitride is used for the processing of mandrel 282.

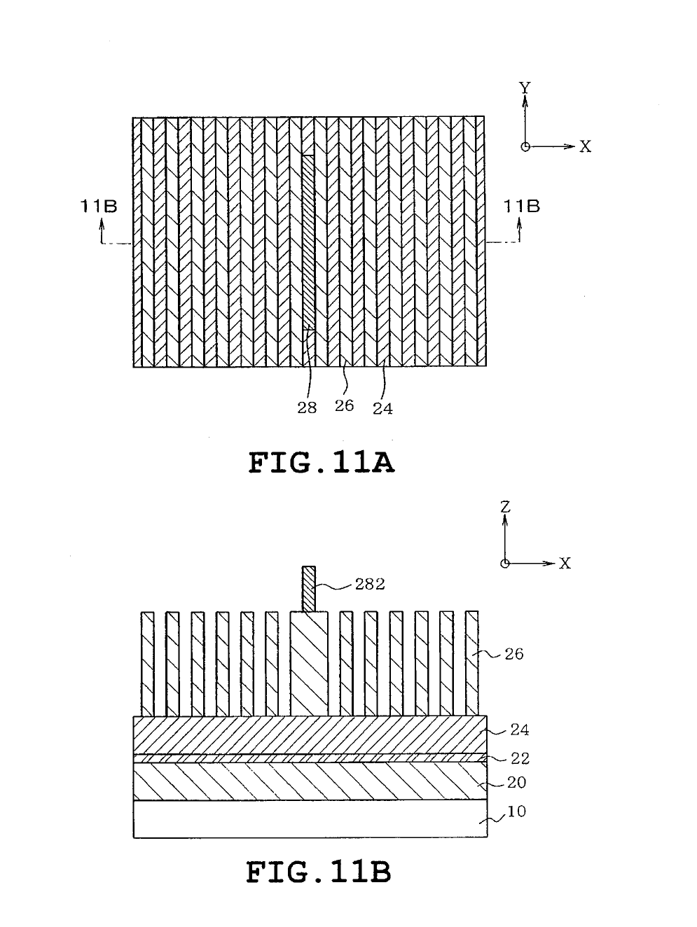

FIGS. 11A and 11B illustrate the process step identical to the process step illustrated in FIGS. 8A and 8B. FIG. 11A illustrates one example of a plan view of a region including cut region CU. FIG. 11B illustrates one example of a vertical cross sectional view taken along line 11B-11B of FIG. 11A.

Because mandrel 282 is formed of silicon nitride film, it is hardly removed by diluted hydrofluoric acid solution. Thus, mandrel 282 remains above first mask film 26 in this step. In the step of forming wiring trenches by etching second interlayer insulating film 24, the etching condition is specified so that the etch rates of mandrel 282 and second interlayer insulating film 24 are substantially the same. It is thus, possible to remove mandrel 282 during the etching of second interlayer insulating film 24. MODIFIED EXAMPLE 2 also provides effects similar to those of the present embodiment.

### Other Embodiments

The foregoing embodiments may be modified as follows.

The embodiments were described through one example of a NAND flash memory device application, but other embodiments may be described through examples of other nonvolatile semiconductor storage devices such as NOR flash memory device or EEPROM or semiconductor storage devices such as DRAM or SRAM.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a memory cell array including a memory cell; and
a circuit element including first wirings and a selection element, the first wirings having a wiring width smaller than a resolution limit of an exposure apparatus;
wherein the first wirings extend in a first direction and are aligned in a second direction crossing with the first direction, and
wherein a second wiring, being one of the first wirings, is cut by at least one out region, and
wherein the first wiring adjacent to the second wiring in the second direction extends continuously in the first direction in a portion adjacent to the cut region in the second direction.

2. The device according to claim 1, wherein a terminating end portion of the second wiring in the cut region has a round shape.

3. The device according to claim 1, wherein a terminating end portion of the second wiring in the cut region has a straight line shape.

4. The device according to claim 1, further comprising a bit line, wherein the second wiring is electrically connected to the bit line.

5. The device according to claim 1, wherein the cut region includes a first cut region and a second cut region and the first cut region and the second cut region are disposed in different locations in the second direction.

6. The device according to claim 5, wherein the first wirings extend in the first direction between the first cut region and the second cut region in the second direction.

7. The device according to claim 1, wherein a vicinity of a terminating end portion of the second wiring is connected to the selection element.

8. The device according to claim 5, wherein the first cut region and the second cut region are disposed above the selection element, and
wherein a vicinity of a terminating end portion of the second wiring cut by the first cut region is connected to one end of the selection element, and a vicinity of a terminating end portion of the second wiring cut by the second cut region is connected to the other end of the selection element.

9. A method of manufacturing a semiconductor storage device comprising:
forming a first insulating film and a first mask film above a semiconductor substrate;
forming mandrels above the first mask film, the mandrels being disposed in a repeating pattern having a first width and extending in a first direction which is repeated in a second direction crossing with the first direction at a first pitch being four times as large as the first width,
conformally forming a second mask film having a first thickness equal to the first width above the first mask film and on the mandrels;
forming a first film above the second mask film;
forming a second film above the first film;
forming a pattern above the second film, the pattern covering at least a portion above a first mandrel being one of the mandrels and not covering any portion above a second mandrel adjacent to the first mandrel in the second direction;
anisotropically etching the second film and the first film and etching back the second mask film using the pattern as a mask to expose an upper surface of the second mandrel and form a sidewall formed of the second mask film along a side surface of the second mandrel;
removing the pattern and the second film;
removing the first film and the second mandrel;
etching back the second mask film to divide the second mask film into a sidewall mask film contacting a side surface of the first mandrel and a third mask film adjacent to the sidewall mask film in the second direction;
etching the first mask film using the third mask film, the first mandrel, the sidewall mask film, and the second mask film as a mask to transfer a pattern to the first mask film;
removing the third mask film, the first mandrel, and the sidewall mask film;
etching the first insulating film using the first mask film having the pattern transferred thereto as a mask to form a trench; and
filling the trench with metal to form a wiring using a polishing technique.

10. The method according to claim 9, wherein the mandrel comprises a carbon film and the second mask film comprises a silicon oxide film.

11. The method according to claim 9, wherein the mandrel comprises a carbon film and the second mask film comprises a titanium oxide.

12. The method according to claim 9, wherein the mandrel comprises a silicon nitride film and the second mask film comprises a silicon oxide film.

13. The method according to claim 9, wherein the first film is a carbon-containing film and the second film is an insulating film.

14. The method according to claim 9, wherein in a cross section in the second direction, an end portion of the pattern is disposed in a range of a second width taken in a direction toward the first mandrel from an end portion of the second mandrel, the second width being twice as large as the first width.

15. The method according to claim 9, wherein removing the first film and the second mandrel is carried out by isotropic etching.

16. The method according to claim 9, wherein removing the first film and the second mandrel is carried out by anisotropic etching.

17. The method according to claim 9, wherein the sidewall mask film and the third mask film have the first width and the sidewall mask film and the third mask are disposed with a spacing taken in the second direction and being equal to the first width.

18. The method according to claim 9, wherein in transferring a pattern to the first mask film, the third mask film and the second mask film are disposed with a spacing taken in the second direction and being equal to the first width.

19. The method according to claim 9, wherein a height of the third mask film is higher than a height of the second mask film.
